(19) United States
(12) Patent Application Publication
(10) Pub. No.: US 2008/0128734 A1
(43) Pub. Date: Jun. 5, 2008

(54) Light-emitting device

(75) Inventors: Min-Hsun Hsieh, Hsinchu (TW); Tzu-Chieh Hsu, Hsinchu (TW); Ta-Cheng Hsu, Hsieh (TW); Wei-Chih Peng, Hsinchu (TW); Ya-Ju Lee, Hsinchu (TW)

Correspondence Address: BACON & THOMAS, PLLC, 625 SLATERS LANE, FOURTH FLOOR, ALEXANDRIA, VA, 22314, US

(73) Assignee: EPISTAR CORPORATION, Hsinchu (TW)

(21) Appl. No.: 11/984,248

(22) Filed: Nov. 15, 2007

Related U.S. Application Data
(63) Continuation-in-part of application No. 11/326,750, filed on Jan. 6, 2006.

(51) Int. Cl. H01L 33/00

(52) U.S. Cl. 257/98; 257/E33.005

(57) ABSTRACT

A light emitting device having a transparent substrate, a light emitting stack, and a transparent adhesive layer is provided. The light emitting stack is disposed above the transparent substrate and comprises a diffusing surface. The transparent adhesive layer is disposed between the transparent substrate and the diffusing surface of the light emitting stack; an index of refraction of the light emitting stack is different from that of the transparent adhesive layer.

### RELATED APPLICATION

This application is a continuation-in-part of U.S. patent application Ser. No. 11/326,750, entitled “LIGHT EMITTING DEVICE”, filed on Jan. 6, 2006, the contents of which are incorporated herein by reference.

### BACKGROUND

1. Technical Field

The present invention relates to a light emitting device and in particular to a light emitting device having a diffusing surface.

2. Description of the Related Art

Light-emitting devices have been employed in a wide variety of applications, including optical displays, traffic lights, data storage apparatus, communication devices, illumination apparatus, and medical treatment equipment. How to improve the light-emitting efficiency of light-emitting devices is an important issue in this art.

Referring to FIG. 1, according to Snell's law, when a light is directed from one material with a refractive index n1 towards another material with an refractive index n2, the light will be refracted if its incident angle is smaller than a critical angle θ_{c}. Otherwise, the light will be totally reflected from the interface between the two materials. In other words, when a light beam generated from a light-emitting diode (LED) travels across an interface from a material of a higher refractive index to a material of a lower refractive index, the angle between the incident light beam and the reflected light beam must be equal or less than 2θ_{c} for the light to be emitted out. It means that when the light generated from the LED travels from an epitaxial layer having a higher refractive index to a medium having a lower refractive index, such as a substrate, air and so on, a portion of the light will be refracted into the medium, and another portion of the light with an incident angle larger than the critical angle will be reflected back to the epitaxial layer of the LED. Owing to the environment surrounding the epitaxial layer of the LED having a lower refractive index, the reflected light is reflected back and forth for several times inside the LED and finally a certain portion of said reflected light is absorbed.

In U.S. Patent Publication No. 2002/0017652 entitled “Semiconductor Chip for Optoelectronics”, an epitaxial layer of a light-emitting device forming on a non-transparent substrate is etched to form a micro-reflective structure having a multiplicity of semi-spheres, pyramids, or cones, then a metal reflective layer is deposited on the epitaxial layer. The top of the micro-reflective structure is bonded to a conductive carrier (silicon wafer), and then the non-transparent substrate of the epitaxial layer is removed. All the light generated from the light-emitting layer and incident to the micro-reflective structure will be reflected back to the epitaxial layer and emitted out of the LED with a direction perpendicular to a light-emitting surface. Therefore, the light will not be restricted by the critical angle any more.

### SUMMARY

The present invention is to provide a light-emitting device comprising a substrate, a light-emitting stack, and a transparent adhesive layer. As embodied and broadly described herein, the light-emitting stack comprising a diffusing surface adjacent to the transparent adhesive layer. The transparent adhesive layer is disposed between the substrate and the diffusing surface of the light-emitting stack.

According to one embodiment of the present invention, the diffusing surface is a rough surface.

According to one embodiment of the present invention, the rough surface is a convex-concave surface.

According to one embodiment of the present invention, the light-emitting stack comprises a first semiconductor layer, a light-emitting layer and a second semiconductor layer. The first semiconductor layer is disposed above the substrate and has the diffusing surface. The light-emitting layer is disposed on a portion of the first semiconductor layer. The second semiconductor layer is disposed on the light-emitting layer.

According to one embodiment of the present invention, the second semiconductor layer has another diffusing surface.

According to one embodiment of the present invention, the light-emitting device further comprises a first electrode and a second electrode. The first electrode is disposed on the first semiconductor layer where the light-emitting layer is not disposed thereon, and the second electrode is disposed on the second semiconductor layer.

According to one embodiment of the present invention, the light-emitting device further comprises a first transparent conductive layer disposed between the first electrode and the first semiconductor layer.

According to one embodiment of the present invention, the light-emitting device further comprises a first reaction layer and a second reaction layer. The first reaction layer is disposed between the substrate and the transparent adhesive layer, and the second reaction layer is disposed between the transparent adhesive layer and the light-emitting stack.

According to one embodiment of the present invention, the light-emitting device further comprises a transparent conductive layer disposed between the second semiconductor layer and the second electrode.

According to one embodiment of the present invention, the light-emitting stack and the transparent adhesive layer have different refractive indices, such that the possibility of light extraction of the light-emitting device is raised, and the light-emitting efficiency is improved, too.

### BRIEF DESCRIPTION OF THE DRAWINGS

The accompanying drawings incorporated herein provide a further understanding of the invention therefore constitute a part of this specification. The drawings illustrating embodiments of the invention, together with the description, serve to explain the principles of the invention.

FIG. 1 is a schematic diagram illustrating the Snell's law.

FIG. 2 is a schematic diagram showing a light field of the present invention.

FIG. 3 is a schematic, cross-sectional view showing a light-emitting device according to a preferred embodiment of the present invention.

FIG. 4 is a schematic, cross-sectional view showing a light-emitting device having two diffusing surfaces according to a preferred embodiment of the present invention.

FIG. 5 is a schematic, cross-sectional view showing a light-emitting device having transparent conductive layers according to a preferred embodiment of the present invention.

FIG. 6 is a schematic, cross-sectional view showing a light-emitting device having reaction layers according to a preferred embodiment of the present invention.

FIG. 7 is a schematic, cross-sectional view showing a light-emitting device according to another preferred embodiment of the present invention.

FIG. 8 is a schematic, cross-sectional view showing a light-emitting device according to another preferred embodiment of the present invention.

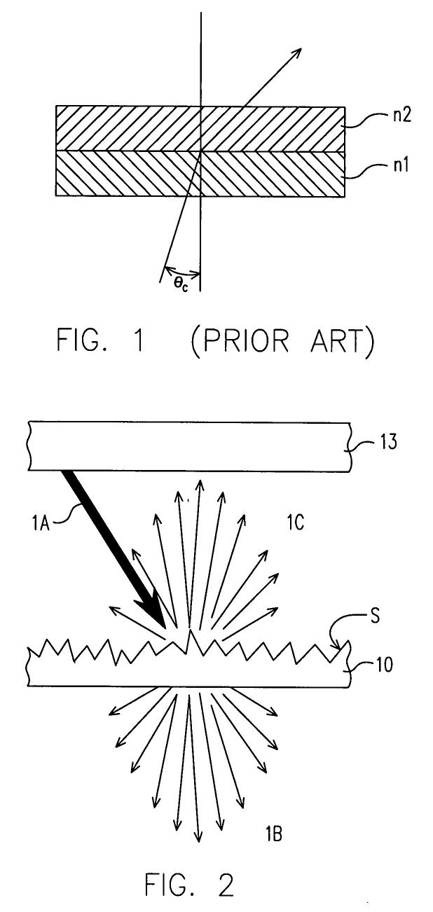

### DETAILED DESCRIPTION OF THE EMBODIMENTS

Reference will now be made in detail to the present preferred embodiments of the invention, examples of which are illustrated in the accompanying drawings. Wherever possible, the same reference numbers are used in the drawings and the descriptions hereof refer to the same or like parts.

FIG. 2 is a schematic diagram showing a light field of the present invention. Referring to FIG. 2, when a light 1A generated from a light-emitting layer 13 is directed towards a diffusing surface S, a portion of the light 1A is refracted to a substrate 10 to form a light field 1B, and another portion of the light 1A is diffused by the diffusing surface S to form a light field 1C. The light, which is restricted to the critical angle, is diffused and redirected by the diffusing surface S to the light-emitting layer 13, and then is extracted from the front of the light-emitting layer 13, therefore the light extraction efficiency is enhanced. If a portion of the diffused light is totally reflected to the diffusing surface S owing to its incident angle greater than the critical angle, it will be diffused again to change its incident angle, thus improving the light extraction efficiency. Therefore, no matter how many times the light experiences the total internal reflection, the light will be diffused by the diffusing surface S to increase the probability of light extraction and enhance the light-emitting efficiency.

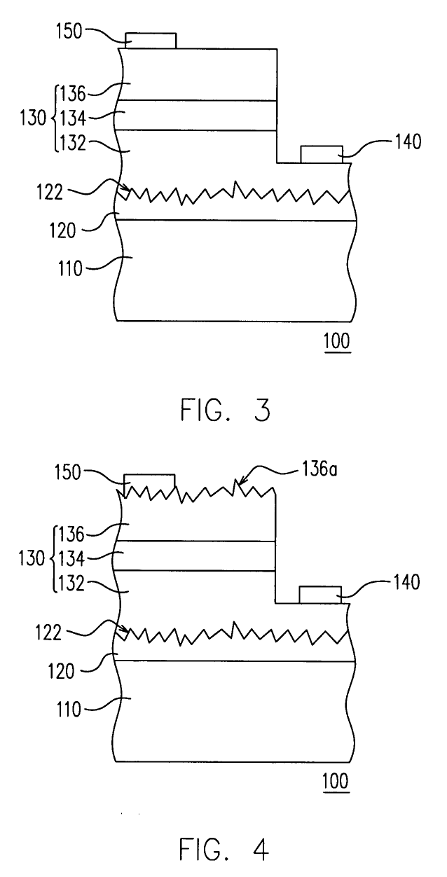

FIG. 3 is a schematic cross-sectional view showing a light-emitting device according to a preferred embodiment of the present invention. The light-emitting device 100 comprises a substrate 110, a transparent adhesive layer 120, a light-emitting stack 130, a first electrode 140, and a second electrode 150. In one embodiment of the present invention, the substrate is a transparent substrate and the material of the substrate 110 is selected from one of the group consisting of GaP, SiC, Al₂O₃, ZnO and glass. The transparent adhesive layer 120 is formed on the substrate 110, and the material of the transparent adhesive layer 120 can be polyimide, benzocyclobutene (BCB), perfluorocyclobutane (PFCB), or indium tin oxide. The light-emitting stack 130 comprises a first semiconductor layer 132 having a first conductivity-type, a light-emitting layer 134, and a second semiconductor layer 136 having a second conductivity-type opposite to the first conductivity-type. The refractive index of the light-emitting stack 130 is different from that of the transparent adhesive layer 120. The first semiconductor layer 132 attaches to the substrate 110 through the transparent adhesive layer 120, and has a first diffusing surface 122 next to the transparent adhesive layer 120. The material of the first semiconductor layer 132, the light-emitting layer 134 and the second semiconductor layer 136 can be AlGaInP, AlN, GaN, AlGaN, InGaN or AlInGaN. An upper surface of the first semiconductor layer 132 has an epitaxy region and an electrode region. The light-emitting layer 134 is formed on the epitaxy region of the first semiconductor layer 132. The second semiconductor layer 136 is formed on the light-emitting layer 134. The first electrode 140 is formed on the electrode region of the first semiconductor layer 132. The second electrode 150 is formed on the second semiconductor layer 136. Referring to FIG. 4, an upper surface of the second semiconductor layer 136 may further comprise a second diffusing surface 136a to increase the light extracted from the diffusing surface 136a. For further increasing the light extracted from the substrate, it is also preferred to form diffusing surfaces on either or both sides of the substrate.

The way to form the first semiconductor layer 132, the light-emitting layer 134 and the second semiconductor layer 136 on the substrate 110 as shown in FIGS. 3 and 4 is to use an epitaxy method, such as MOVPE method (Metallic Organic Vapor Phase Epitaxy). The diffusing surfaces 122 or 136a, can be rough surfaces formed during the exitaxy process by carefully tuning and controlling the process parameters, such as gas flow rate, chamber pressure, chamber temperature etc. The diffusing surfaces can also be formed by removing a part of the first semiconductor layer 132 or the second semiconductor layer 136 by wet etching or dry etching to form a periodic, quasi-periodic, or random pattern.

In another embodiment of the present invention, the diffusing surface 122 of the first semiconductor layer 132 or the diffusing surfaces 136a of the second semiconductor layer 136 comprises a plurality of micro-protrusions. The shape of the micro-protrusions can be a semi-sphere, a pyramid, or a pyramid polygon. The light extraction efficiency is therefore enhanced by the surface roughened in a manner of micro-protrusions.

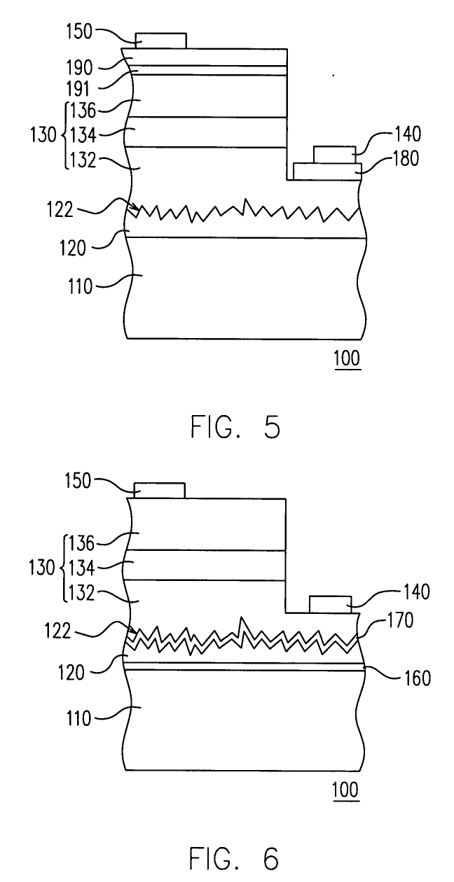

In one embodiment of the present invention, referring to FIG. 5, a first transparent conductive layer 180 is selectively disposed between the first electrode 140 and the first semiconductor layer 132. The material of the first transparent conductive layer 180 comprises indium tin oxide, cadmium tin oxide, antimony tin oxide, zinc aluminum oxide, or zinc tin oxide. Similarly, a second transparent conductive layer 190 is selectively disposed between the second semiconductor layer 136 and the second electrode 150. The second transparent conductive layer 190 is mainly served to spread current in at least lateral direction. In one embodiment, the thickness of the second transparent conductive layer 190 is thick enough such that current is swiftly laterally spread throughout the second transparent conductive layer 190. The thickness (t) of the transparent conductive layer 190 is not less than 400 nm. In another embodiment, the second transparent conductive layer 190 is in a shape of rectangle complying with the shape of the light-emitting device, for example, the length (L) of the transparent conductive layer 190 is at least twice of the width (W) of the transparent conductive layer 190, preferably L/W is around 2˜5. The thickness of the second transparent conductive layer 190 is preferably around 400 nm to 1000 nm. The sheet resistance is preferably less than 9 ohm/square. The material of the second transparent conductive layer 190 comprises transparent conductive oxide, such as indium tin oxide, cadmium tin oxide, antimony tin oxide, zinc aluminum oxide, or zinc tin oxide.

In another embodiment, the light-emitting device 100 further comprises a conductive inter-layer (CIL) 191 interposing between the transparent conductive layer 190 and the second semiconductor layer 136 for improving the in-between contact resistance. The conductive inter-layer 191 comprises a semiconductor material having a conductivity-type opposite to that of the second semiconductor layer 136. For example, in a GaN-based light-emitting device, the conductive inter-layer 191 comprises heavily Si-doped InGaN, and the Si dopant concentration is around the level of 10¹⁸ to 10²⁰ cm⁻³. A tunneling junction is formed between the conductive inter-layer 191 and the second semiconductor layer 136, and an ohmic contact is also formed between the conductive inter-layer 191 and the transparent conductive layer 190 such that the series resistance of the device is reduced.

Further referring to FIG. 6, a first reaction layer 160 can be selectively disposed between the substrate 110 and the transparent adhesive layer 120, and a second reaction layer 170 can be selectively disposed between the transparent adhesive layer 120 and the first semiconductor layer 132, thereby increasing the adhesion of the transparent adhesive layer 120. The material of the first reaction layer 160 and the second reaction layer 170 can be SiNx, Ti or Cr.

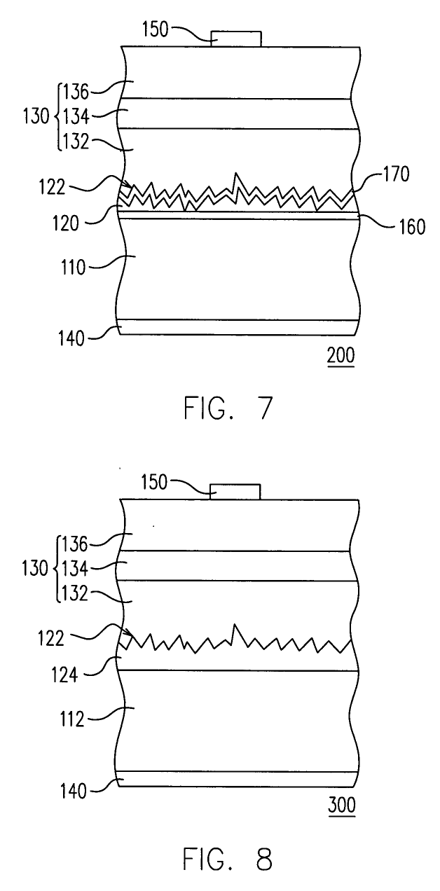

FIG. 7 is a schematic cross-sectional view showing a vertical-type light-emitting device 200 according to another preferred embodiment of the present invention. The substrate 110 is a transparent conductive substrate, for example, ZnO. The first semiconductor layer 132 with the second reaction layer 170 underneath is coupled to a gel-state transparent adhesive layer 120, and the protrusion part of the second reaction layer 170 penetrates through the transparent adhesive layer 120 and ohmically contacts with the first reaction layer 160 in the case of the first reaction layer 160 and the second reaction layer 170 both being conductive. A first electrode 140 is formed on the lower surface of the substrate 110, and a second electrode 150 is formed on the upper surface of the second semiconductor layer 136. Similarly, a transparent conductive layer (not shown) can be selectively disposed between the second electrode 150 and the second semiconductor layer 136. The material of the transparent conductive layer comprises indium tin oxide, cadmium tin oxide, antimony tin oxide, zinc aluminum oxide or zinc tin oxide.

FIG. 8 is a schematic cross-sectional view showing a light-emitting device according to another preferred embodiment of the present invention. Referring to FIG. 8, the structure of the light-emitting device 300 is similar to that of the light-emitting device 100 shown in FIG. 3. The difference between them is that a transparent conductive adhesive layer 124 replaces the transparent adhesive layer 120, such that the light-emitting device 300 is electrically conductive vertically. The transparent conductive adhesive layer 124 is composed of intrinsically conductive polymer or polymer having conductive material distributed therein. The conductive material comprises indium tin oxide, cadmium tin oxide, antimony tin oxide, zinc oxide, zinc tin oxide, Au or Ni/Au. The first electrode 140 is formed under a transparent conductive substrate 112, and the second electrode 150 is formed on the second semiconductor layer 136.

In one embodiment of the present invention, the light-emitting device 300 further comprises a transparent conductive layer (not shown) disposed between the second electrode 150 and the second semiconductor layer 136. The material of the transparent conductive layer comprises indium tin oxide, cadmium tin oxide, antimony tin oxide, zinc aluminum oxide or zinc tin oxide.

It will be apparent to those skilled in the art that various modifications and variations can be made to the structures in accordance with the present invention without departing from the scope or spirit of the invention. In view of the foregoing, it is intended that the present invention cover modifications and variations of this invention provided they fall within the scope of the following claims and their equivalents.

What is claimed is:

1. A light-emitting device, comprising:
a substrate;
a light-emitting stack above the transparent substrate and having a first diffusing surface;
a transparent adhesive layer between the substrate and the first diffusing surface; and
a first transparent conductive oxide layer above the light-emitting stack;
wherein the thickness of the first transparent conductive oxide layer is thick enough such that current is laterally spreaded substantially throughout the transparent conductive layer.

2. The light-emitting device according to claim 1, wherein the thickness of the first transparent conductive oxide layer is not less than 400 nm.

3. The light-emitting device according to claim 1, wherein the sheet resistance of the first transparent conductive oxide layer is less than 9 ohms/square.

4. The light-emitting device according to claim 1, wherein the length of the first transparent conductive oxide layer is 2 to 5 times of the width of the first transparent conductive oxide layer.

5. The light-emitting device according to claim 1, wherein the first transparent conductive layer comprises a material selected from the group consisting of indium tin oxide, cadmium tin oxide, antimony tin oxide, zinc aluminum oxide, and zinc tin oxide.

6. The light-emitting device according to claim 1, wherein the substrate is transparent and comprises a material selected from the group consisting of GaP, SiC, Al₂O₃, ZnO, and glass.

7. The light-emitting device according to claim 1, wherein the transparent adhesive layer comprises a material selected from the group consisting of polyimide, benzocyclobutene (BCB), perfluorocyclobutane (PFCB), and indium tin oxide.

8. The light-emitting device according to claim 1, wherein the first diffusing surface comprises a rough surface.

9. The light-emitting device according to claim 8, wherein the rough surface comprises a convex-concave surface.

10. The light-emitting device according to claim 1, wherein the light-emitting stack comprises:
a first semiconductor layer formed above the substrate and having the first diffusing surface and having a first conductivity-type;
a light-emitting layer formed on the first semiconductor layer; and
a second semiconductor layer formed on the light-emitting layer and having a second conductivity-type different from the first conductivity-type.

11. The light-emitting device according to claim 10, further comprising a conductive inter-layer for forming a tunneling junction associating with the second semiconductor layer.

12. The light-emitting device according to claim 11, wherein the conductive inter-layer comprises a heavily-doped semiconductor material having the first conductivity-type.

13. The light-emitting device according to claim 10, wherein the second semiconductor layer has a second diffusing surface.

14. The light-emitting device according to claim 10, further comprising a first electrode and a second electrode.

15. The light-emitting device according to claim 14, wherein the first semiconductor layer comprises a first region where the light-emitting layer, the second semiconductor layer, and the second electrode are sequentially formed thereon, and a second region where the first electrode is formed thereon.

16. The light-emitting device according to claim 15, further comprising a second transparent conductive layer between the first electrode and the first semiconductor layer.

17. The light-emitting device according to claim 16, wherein the first transparent conductive layer comprises a material selected from the group consisting of indium tin oxide, cadmium tin oxide, antimony tin oxide, zinc aluminum oxide, and zinc tin oxide.

18. The light-emitting device according to claim 1, further comprising a first reaction layer and a second reaction layer, wherein the first reaction layer is between the substrate and the transparent adhesive layer, and the second reaction layer is between the transparent adhesive layer and the light-emitting stack.

19. The light-emitting device according to claim 14, wherein the first electrode is on the second semiconductor layer and the second electrode is under the substrate.

20. The light-emitting device according to claim 19, wherein the substrate is conductive.

21. The light-emitting device according to claim 20, wherein the transparent adhesive layer is a conductive layer comprising a material selected from the group consisting of intrinsically conductive polymer and polymer having conductive material distributed therein.

22. The light-emitting device according to claim 21, further comprising a first reaction layer and a second reaction layer, wherein the first reaction layer is between the substrate and the transparent adhesive layer, and the second reaction layer is between the transparent adhesive layer and the light-emitting stack.

23. The light-emitting device according to claim 22, wherein the first reaction layer and the second reaction layer are conductive.

24. The light-emitting device according to claim 23, wherein the first diffusing surface comprises a plurality of micro-protrusions, and the second reaction layer is in ohmic contact with the first reaction layer with the existence of the protrusions penetrating through the transparent adhesive layer.

25. The light-emitting device according to claim 23, wherein the first diffusing surface comprises a convex-concave surface, and the second reaction layer is in ohmic contact with the first reaction layer with the existence of a convex part of the convex-concave surface penetrating through the transparent adhesive layer.
